(19) United States
(12) Patent Application Publication
(10) Pub. No.: US 2022/0077426 A1
(43) Pub. Date: Mar. 10, 2022

(54) LIGHT-EMITTING DIODE, DISPLAY PANEL, DISPLAY APPARATUS AND LIGHT-EMITTING APPARATUS

(71) Applicant: BOE Technology Group Co., Ltd., Beijing (CN)

(72) Inventors: Fudong CHEN, Beijing (CN); Qingyu HUANG, Beijing (CN); Juan ZHANG, Beijing (CN); Zhiqiang JIAO, Beijing (CN)

(21) Appl. No.: 17/362,819

(22) Filed: Jun. 29, 2021

(30) Foreign Application Priority Data
Sep. 8, 2020 (CN) 202010935993.7

(51) Int. Cl. H01L 51/52; H01L 51/50; H01L 51/00; H01L 51/56

(52) U.S. Cl. CPC H01L 51/5275; H01L 51/5056; H01L 51/5072; H01L 51/5088; H01L 51/5092; H01L 51/5218; H01L 51/0085; H01L 51/001; H01L 51/56; H01L 51/0037; H01L 51/0035; H01L 51/0077; H01L 51/0072; H01L 51/5293

(57) ABSTRACT

A light-emitting diode includes an anode layer, a hole injection layer, a hole transport layer, a light-emitting layer, an electron transport layer, an electron injection layer and a cathode layer which are laminated sequentially. The light-emitting diode meets at least one of the following conditions: a refractive index of the hole transport layer is greater than a refractive index of the light-emitting layer; and a refractive index of the electron transport layer is greater than the refractive index of the light-emitting layer.

### CROSS REFERENCE TO RELATED APPLICATION

This application claims priority to Chinese Patent Application No. 202010935993.7, filed on Sep. 8, 2020 and entitled “LIGHT-EMITTING DIODE, DISPLAY PANEL, DISPLAY APPARATUS AND LIGHT-EMITTING APPARATUS”, the disclosure of which is herein incorporated by reference in its entirety.

### TECHNICAL FIELD

The present disclosure relates to the field of display technologies, and in particular relates to a light-emitting diode, a display panel, a display apparatus and a light-emitting apparatus.

### BACKGROUND

When photons are incident onto the surface of a photosensitive material, some of the photons excite the photosensitive material to generate electron hole pairs, thereby forming an electric current, and some of the photons are absorbed. External quantum efficiency (EQE) is a ratio of the quantity of collected electrons (through processes such as internal electron hole recombination) to the quantity of all incident photons. Internal quantum efficiency (IQE) is a ratio of the quantity of produced electrons (electron loss caused by skipping of processes such as electron hole recombination) to the quantity of absorbed photons.

At present, the IQE of a light-emitting diode generally can reach about 100%, but the EQE of the light-emitting diode is still at a relatively low level (20% to 30%), because for a planar light-emitting diode, based on the principle of electromagnetic wave propagation in a multi-dielectric film, for electromagnetic waves emitted by photons after exciton recombination transition in the light-emitting diode, a large proportion of photons (more than 70%) are confined in the light-emitting diode or consumed by Surface Plasmon Polaritons (SPP), due to total reflection or a mixed excitation state formed by near-field photons and oscillating electrons on a metal surface, such that the photons cannot be emitted. As a result, the EQE of the light-emitting diode is less than 30%.

### SUMMARY

The present disclosure provides a light-emitting diode, a display panel, a display apparatus and a light-emitting apparatus.

In a first aspect, the present disclosure provides a light-emitting diode. The light-emitting diode includes an anode layer, a hole injection layer, a hole transport layer, a light-emitting layer, an electron transport layer, an electron injection layer and a cathode layer which are laminated sequentially; and the light-emitting diode meets at least one of the following conditions: a refractive index of the hole transport layer is greater than a refractive index of the light-emitting layer; and a refractive index of the electron transport layer is greater than the refractive index of the light-emitting layer.

In an implementation of this embodiment of the present disclosure, the light-emitting diode meets the following conditions: the refractive index of the hole transport layer is not less than 2; the refractive index of the electron transport layer is not less than 2; a refractive index of the hole injection layer is not greater than 1.8; and a refractive index of the electron injection layer is not greater than 1.8.

In an implementation of this embodiment of the present disclosure, the refractive index of the hole transport layer ranges from 2 to 2.5; the refractive index of the electron transport layer ranges from 2 to 2.5; the refractive index of the hole injection layer ranges from 1.5 to 1.8; and the refractive index of the electron injection layer ranges from 1.5 to 1.8.

In an implementation of this embodiment of the present disclosure, both the refractive index of the hole transport layer and the refractive index of the electron transport layer are 2.2; and both the refractive index of the hole injection layer and the refractive index of the electron injection layer are 1.6.

In an implementation of this embodiment of the present disclosure, the hole injection layer is made of PEDOT:PSS; and the hole transport layer is made of MoO₃.

In an implementation of this embodiment of the present disclosure, the electron transport layer is made of Liq; and the electron injection layer is made of Bphen:Li.

In an implementation of this embodiment of the present disclosure, the refractive index of the light-emitting layer is not greater than 1.7.

In an implementation of this embodiment of the present disclosure, the light-emitting diode further includes a reflective layer, wherein the anode layer is disposed between the reflective layer and the hole injection layer; and the light-emitting diode further meets at least one of the following conditions:

the refractive index of the hole transport layer is greater than the refractive index of the light-emitting layer, and a refractive index of the hole injection layer is less than the refractive index of the light-emitting layer; and

the refractive index of the electron transport layer is greater than the refractive index of the light-emitting layer, while a refractive index of the electron injection layer is less than the refractive index of the light-emitting layer.

In an implementation of this embodiment of the present disclosure, the light-emitting diode further includes an optical coupling layer disposed on a surface of the cathode layer away from the anode layer, wherein the optical coupling layer includes at least one sub-layer, a material of at least one of the at least one sub-layer being the same as a material of at least one of the hole transport layer and the electron transport layer.

In an implementation of this embodiment of the present disclosure, the optical coupling layer includes a capping layer (CPL) and a lithium fluoride layer; wherein the CPL is disposed between the cathode layer and the lithium fluoride layer, and a material of the hole transport layer is the same as that of the CPL.

In an implementation of this embodiment of the present disclosure, the light-emitting diode is an LED device or an OLED device.

In a second aspect, the present disclosure provides a display panel. The display panel includes a substrate and a light-emitting diode disposed on the substrate, and the light-emitting diode is the light-emitting diode described in any one of the implementations in the first aspect.

In a third aspect, the present disclosure provides a display apparatus. The display apparatus includes a power supply component and the display panel described in the second aspect, and the power supply component is configured to supply power to the display panel.

In a fourth aspect, the present disclosure provides a light-emitting apparatus. The light-emitting apparatus includes a substrate and a light-emitting diode disposed on the substrate; and the light-emitting diode is the light-emitting diode described in any one of the implementations in the first aspect.

### BRIEF DESCRIPTION OF THE DRAWINGS

FIG. 1 is a schematic structural diagram of a light-emitting diode according to an embodiment of the present disclosure;

FIG. 2 is a schematic structural diagram of a light-emitting diode according to an embodiment of the present disclosure;

FIG. 3 is a schematic structural diagram of a light-emitting diode according to an embodiment of the present disclosure;

FIG. 4 is a flowchart showing a method for manufacturing a light-emitting diode according to an embodiment of the present disclosure;

FIG. 5 is a luminescence spectrum diagram of experimental device 1 according to an embodiment of the present disclosure;

FIG. 6 is a luminescence spectrum diagram of contrast device 1 according to an embodiment of the present disclosure;

FIG. 7 is a luminescence spectrum diagram of experimental device 2 according to an embodiment of the present disclosure;

FIG. 8 is a luminescence spectrum diagram of contrast device 2 according to an embodiment of the present disclosure;

FIG. 9 is a luminescence spectrum diagram of experimental device 3 according to an embodiment of the present disclosure;

FIG. 10 is a luminescence spectrum diagram of contrast device 3 according to an embodiment of the present disclosure;

FIG. 11 is an electroluminescence spectrum diagram of experimental device 4 and contrast device 4 according to an embodiment of the present disclosure; and

FIG. 12 is a J-V curve chart of experimental device 4 and contrast device 4 according to an embodiment of the present disclosure.

### DETAILED DESCRIPTION

The embodiments of the present disclosure are described hereinafter in detail. The embodiments described hereinafter are examples and merely intended for illustration, but cannot be construed as limitations to the present disclosure. Where no specific technology or condition is specified, the embodiments are implemented with technologies or conditions described in documents in the art or according to the product specification. Materials used without indicating the manufacturer's names are conventional products that can be purchased in the market.

In the related art, by improving the external structure of a device, such as the optical grating, the lens, or the photonic crystal, the waveguide effect in the device is destroyed, and thus the SPP loss is reduced. However, with the method in the related art, problems such as increase in the complexity of a manufacturing process, destroy of the electrical structure of a light-emitting diode, and destroy of a micro-cavity gain may be incurred, which leads to difficulty in mass production.

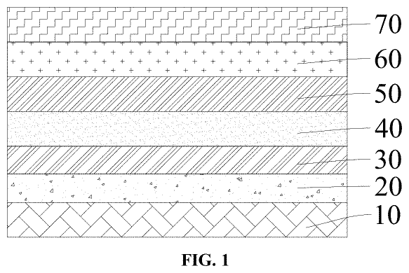

FIG. 1 is a schematic structural diagram of a light-emitting diode according to an embodiment of the present disclosure. As shown in FIG. 1, the light-emitting diode includes an anode layer 10, a hole injection layer (HIL) 20, a hole transport layer (HTL) 30, a light-emitting layer 40, an electron transport layer (ETL) 50, an electron injection layer (EIL) 60 and a cathode layer 70 which are laminated sequentially. The light-emitting diode meets at least one of the following conditions: a refractive index of the hole transport layer 30 is greater than that of the light-emitting layer 40; and a refractive index of the electron transport layer 50 is greater than that of the light-emitting layer 40.

The anode layer 10 and the cathode layer 70 define a micro-cavity structure, i.e., the cavity between the anode layer 10 and the cathode layer 70. The micro-cavity structure can improve the light-emitting efficiency of the light-emitting diode, which is referred to as micro-cavity gain for short. When light is emitted from the cathode layer 70, the thickness of the cathode layer 70 is reduced in the related art to improve the light extraction efficiency and increase light transmittance of the cathode layer 70. As a result, the micro-cavity gain is weakened. In this embodiment of the present disclosure, the refractive index of the hole transport layer 30 is greater than that of the light-emitting layer 40, so that the hole transport layer 30 and the light-emitting layer 40 form a lens. Light is refracted and reflected repeatedly in the lens, which can increase emergence of light, to enhance the weakened micro-cavity gain caused by thinning of the cathode layer 70. That is, good micro-cavity gain is guaranteed effectively. The refractive index of the electron transport layer 50 is greater than that of the light-emitting layer 40, such that the micro-cavity structure can also be changed, to effectively guarantee good micro-cavity gain. Therefore, the above arrangement can effectively increase the EQE (or light extraction efficiency) of the light-emitting diode, and also guarantee good electrical performance, such that the light-emitting diode has excellent usability. In addition, the EQE of the light-emitting diode in the present disclosure can be greatly increased so as to improve its light-emitting efficiency, without introducing an external structure to destroy the electrical basis of the light-emitting diode.

Both the refractive indexes of the hole transport layer 30 and the electron transport layer 50 are greater than that of the light-emitting layer 40, and the light-emitting layer 40 is disposed between the hole transport layer 30 and the electron transport layer 50. By forming the structure including a high refractive layer, a low refractive layer and a high refractive layer sequentially, the weakened micro-cavity gain caused by thinning of the cathode layer 70 is enhanced, which effectively guarantees the good micro-cavity gain.

In an implementation of this embodiment of the present disclosure, the light-emitting diode further includes a reflective layer. The anode layer 10 is disposed between the reflective layer and the hole injection layer 20, and the light-emitting diode further meets at least one of the following conditions: the refractive index of the hole transport layer 30 is greater than that of the light-emitting layer 40, and the refractive index of the hole injection layer 20 is less than that of the light-emitting layer 40; and the refractive index of the electron transport layer 50 is greater than that of the light-emitting layer 40, and the refractive index of the electron injection layer 60 is less than that of the light-emitting layer 40.

In this embodiment of the present disclosure, to improve light extraction efficiency, a reflective layer is generally disposed on the side of the anode layer 10 away from the hole injection layer 20, such that light is reflected by the reflective layer when light is transmitted to the reflective layer, and penetrates through the anode layer 10 to be emitted from the cathode layer 70. Generally, the reflective layer is a silver layer, and the anode layer 10 is an indium tin oxide (ITO) layer. Because the reflective layer is made of a metal material, the light interacts with electrons vibrating freely on the surface of the reflective layer, to generate electron dilatational waves propagating along the surface of the reflective layer. The electron dilatational waves are called surface plasmons (SPs). An electromagnetic wave mode generated by the interaction between light and the free electrons on the surface of the reflective layer is called surface plasmon polaritons (SPPs). During the interaction between light and the free electrons, the free electrons oscillate collectively under irradiation of light with the same resonance frequency as the free electrons, such that the light propagates along the surface of the reflective layer and cannot be emitted from the reflective layer, which results in loss, which is called surface plasmon polariton loss. Therefore, the optical efficiency of the light-emitting diode is low. In this embodiment of the present disclosure, the refractive index of the hole transport layer 30 is greater than that of the light-emitting layer 40, and the refractive index of the hole injection layer 20 is less than that of the light-emitting layer 40, such that the surface plasmon polaritons on interfaces on two sides of the anode layer 10 are coupled. Coupling between the surface plasmon polaritons on the interfaces on two sides of the anode layer 10 refers to that the surface plasmon polaritons are converted to light by interaction, and thus the quantity of the surface plasmon polaritons reduces accordingly. As the surface plasmon polaritons can be coupled, the light extraction efficiency can be improved effectively.

Similarly, the cathode layer 70 is usually a metal layer and also has surface plasmon polariton loss. Therefore, the optical efficiency of the light-emitting diode is reduced. Because the refractive index of the electron transport layer 50 is greater than that of the light-emitting layer 40, and the refractive index of the electron injection layer 60 is less than that of the light-emitting layer 40, the surface plasmon polaritons on interfaces on two sides of the cathode layer 70 are coupled, which also effectively improves the light extraction efficiency.

In an implementation of this embodiment of the present disclosure, the refractive index of the hole injection layer 20 is not greater than 1.8; and the refractive index of the electron injection layer 60 is not greater than 1.8, such that the hole transport layer 30 and the electron transport layer 50 have high refractive indexes. The light-emitting layer 40 is disposed between the hole transport layer 30 and the electron transport layer 50, such that the weakened micro-cavity gain caused by thinning of the cathode layer 70 can be enhanced by the high total reflection ratio from the layer with a high-refractive index to the layer with a lower-refractive index (the refractive index of the light-emitting layer is generally less than 2), thereby effectively guaranteeing good micro-cavity gain. The refractive index of the electron injection layer 60 adjacent to the cathode layer 70 and the refractive index of the hole injection layer 30 adjacent to the anode layer 10 are low, which effectively reduces SPP loss, and optimizes the modal distribution curve of internal photons of the light-emitting diode, to increase the modal part that can be emitted out. Therefore, the above arrangement can effectively increase the EQE (or light extraction efficiency) of the light-emitting diode, that is, improve the optical coupling output efficiency of the light-emitting diode; and can also guarantee good electrical performance, such that the light-emitting diode has excellent usability. In addition, the EQE of the light-emitting diode in the present disclosure can be greatly increased to improve its light-emitting efficiency, without introducing an external structure to destroy the electrical basis of the light-emitting diode.

In this embodiment of the present disclosure, the refractive index of the hole transport layer 30 ranges from 2 to 2.5; and the refractive index of the electron transport layer 50 ranges from 2 to 2.5. For example, at least one of the refractive index of the hole transport layer 30 and the refractive index of the electron transport layer 50 is 2, 2.1, 2.2, 2.3, 2.4, or 2.5. Therefore, SPP loss of the light-emitting diode can be effectively reduced to increase its EQE. If at least one of the refractive index of the hole transport layer 30 and the refractive index of the electron transport layer 50 is less than 2, improvement on the EQE of the light-emitting diode is not good. It should be noted that, theoretically, the greater the refractive indexes of the hole transport layer 30 and the electron transport layer 50 are, the better the improvement on the EQE is. However, at present, it is difficult to find a material whose refractive index is greater than 2.5 and which can satisfy the requirements on the usability of the hole transport layer 30 and the electron transport layer 50.

In this embodiment of the present disclosure, the refractive index of the hole injection layer 20 ranges from 1.5 to 1.8, and the refractive index of the electron injection layer 60 ranges from 1.5 to 1.8. For example, at least one of the refractive index of the hole injection layer 20 and the refractive index of the electron injection layer 60 is 1.5, 1.55, 1.6, 1.65, 1.7, 1.75, or 1.8. Therefore, SPP loss of the light-emitting diode can be effectively reduced to increase its EQE. If at least one of the refractive index of the hole injection layer 20 and the refractive index of the electron injection layer 60 is greater than 1.8, improvement on the EQE of the light-emitting diode is not good. It should be noted that, theoretically, the smaller the refractive indexes of the hole injection layer 20 and the electron injection layer 60 are, the better the improvement on the EQE is. However, at present, it is difficult to find a material whose refractive index is less than 1.5 and which can satisfy the requirements on usability of the hole injection layer 20 and the electron injection layer 60.

In this embodiment of the present disclosure, both the refractive indexes of the hole transport layer 30 and the electron transport layer 50 are 2.2; and both the refractive indexes of the hole injection layer 20 and the electron injection layer 60 are 1.6, such that the SPP loss of the light-emitting diode can be reduced most effectively, to improve optical coupling output efficiency of the light-emitting diode to the most extent. In addition, the electrical performance of the light-emitting diode is not influenced.

In this embodiment of the present disclosure, the refractive index of the light-emitting layer 40 is less than or equal to 1.7. For example, the refractive index of the light-emitting layer is 1.7, 1.68, 1.65, 1.62, 1.6, 1.58, 1.55, 1.52, or 1.5, such that the EQE of the light-emitting diode can be further increased.

In this embodiment of the present disclosure, the light-emitting layer 40 includes one of a red-light-emitting layer, a green-light-emitting layer, and a blue-light-emitting layer. As such, when the light-emitting diode is an OLED device and applied to a display apparatus, the display effect of the display apparatus can be achieved effectively.

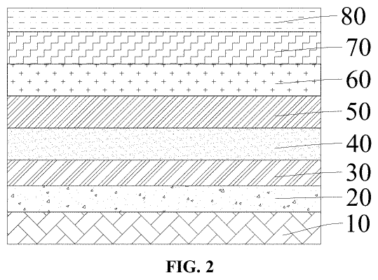

FIG. 2 is a schematic structural diagram of a light-emitting diode according to an embodiment of the present disclosure. Referring to FIG. 2, the light-emitting diode further includes an optical coupling layer 80. The optical coupling layer 80 is disposed on the surface of the cathode layer 70 away from the anode layer 10. At least part of the materials of the optical coupling layer 80 are the same as that of the hole transport layer 30 or the electron transport layer 50, such that the optical parameter of the optical coupling layer 80 is approximate to that of the hole transport layer 30 or the electron transport layer 50. As such, when light is transmitted from the hole transport layer 30 or the electron transport layer 50 to the optical coupling layer 80, light is emitted from the optical coupling layer 80 more easily, which can further increase the EQE of the light-emitting diode.

Here, the optical coupling layer may be of a laminated structure including a plurality of layers made of different materials, as long as the material of at least one of the layers is the same as that of the hole transport layer 30 or the electron transport layer 50.

In this embodiment of the present disclosure, the optical coupling layer 80 includes a capping layer (CPL) and a lithium fluoride (LiF) layer. The CPL is disposed between the cathode layer 70 and the lithium fluoride layer. For example, the material of the CPL is the same as that of the hole transport layer 30 or the electron transport layer 50.

In this embodiment of the present disclosure, the hole injection layer 20 is made of PEDOT:PSS; the hole transport layer 30 is made of MoO3 (molybdenum trioxide); the electron transport layer 50 is made of Liq (8-Hydroxyquinolinolato-lithium); and the electron injection layer 60 is made of Bphen:Li. The optical coupling layer 80 includes the CPL and the LiF layer. In the light-emitting diode made of the foregoing materials, the refractive index of the hole injection layer 20 is 1.52, the refractive index of the hole transport layer 30 is 2.2, the refractive index of the electron transport layer 50 is 2.2, and the refractive index of the electron injection layer 60 is 1.7. Therefore, the light-emitting diode has a high EQE and good electrical performance, which can guarantee the luminous intensity and usability of the light-emitting diode.

In the embodiments of the present disclosure, there is no special requirement on the thickness of each layer. Those skilled in the art can flexibly set the thickness according to actual conditions such as light colors of different light-emitting layers, which is not repeated herein.

In the embodiments of the present disclosure, there is on special requirement on the specific materials of the cathode layer 70 and the anode layer 10. Those skilled in the art can flexibly choose the materials according to actual conditions. In some embodiments, materials of the cathode layer 70 include, but are not limited to, at least one of silver, magnesium and molybdenum, and materials of the anode layer 10 include, but are not limited to, laminated silver and ITO or laminated ITO, silver and ITO, such that the cathode layer 70 and the anode layer 10 have better conductivity, and their material sources are wide. The resistance per unit area of ITO in the anode layer is less than 30 Ω/□.

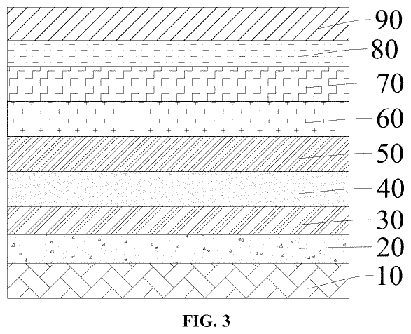

FIG. 3 is a schematic structural diagram of a light-emitting diode according to an embodiment of the present disclosure. Referring to FIG. 3, the light-emitting diode further includes an encapsulation layer 90. The encapsulation layer 90 is disposed on the side of the optical coupling layer 80 away from the anode layer 10. In some embodiments, the encapsulation layer includes a first inorganic layer, an organic layer and a second inorganic layer which are laminated sequentially. Here, materials of the first inorganic layer and the second inorganic layer include, but are not limited to, silicon nitride, silicon dioxide, and silicon oxynitride. The organic layer may be an ink jet printing (IJP) layer, and the material of the organic layer includes, but is not limited to, ink, so as to encapsulate the light-emitting layer effectively, to prevent water and oxygen from entering the light-emitting layer to impact its light-emitting performance.

In the embodiments of the present disclosure, the light-emitting diode is an LED device or an OLED device.

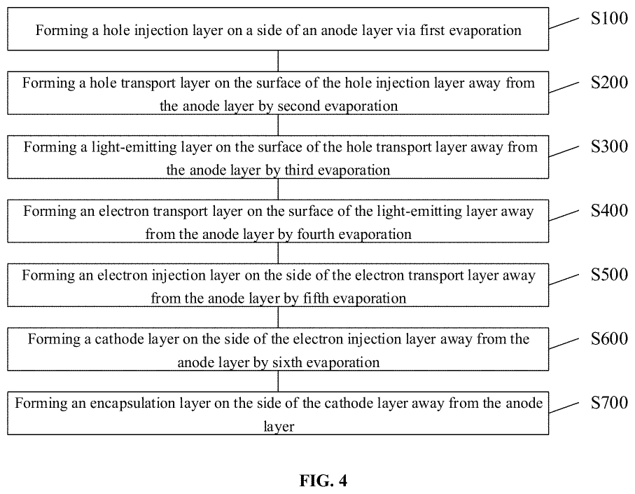

FIG. 4 is a flowchart of a method for manufacturing a light-emitting diode according to an embodiment of the present disclosure. Referring to FIG. 4, the method includes the following steps.

In step S100, a hole injection layer is formed on a side of an anode layer by first evaporation.

In the present disclosure, manufacture of a red light-emitting diode is taken as an example for introduction. The anode layer is formed by photolithography. Before forming a red fluorescent light-emitting layer, the anode layer needs to be washed in ultrasonic environment of deionized water, acetone and absolute ethyl alcohol in sequence, blow-dried with nitrogen, and then treated with oxygen plasma.

In step S200, a hole transport layer is formed on the surface of the hole injection layer away from the anode layer by second evaporation.

In step S300, a light-emitting layer is formed on the surface of the hole transport layer away from the anode layer by third evaporation.

In step S400, an electron transport layer is formed on the surface of the light-emitting layer away from the anode layer by fourth evaporation.

In step S500, an electron injection layer is formed on the side of the electron transport layer away from the anode layer by fifth evaporation.

In step S600, a cathode layer is formed on the side of the electron injection layer away from the anode layer by sixth evaporation.

In step S700, an encapsulation layer is formed on the side of the cathode layer away from the anode layer.

Here, each of the evaporation rates of the first evaporation, the second evaporation, the third evaporation, the fourth evaporation, the fifth evaporation and the sixth evaporation ranges from 8 nm/s to 30 nm/s, for example, 8 nm/s, 10 nm/s, 12 nm/s, 14 nm/s, 16 nm/s, 18 nm/s, 20 nm/s, 22 nm/s, 24 nm/s, 26 nm/s, 28 nm/s, or 30 nm/s. Therefore, the anode layer, the cathode layer, the light-emitting layer, the electron transport layer, the hole transport layer, the hole injection layer, the electron injection layer and the like with good performance and uniform thickness can be prepared. In addition, in the evaporation process for forming the anode layer, the evaporation rate of a silver electrode layer is 30 nm/s to 40 nm/s.

In some embodiments, a metal mask may be used to prepare the cathode layer via evaporation with an evaporation rate of 30 nm/s, and an open mask may be used to prepare the anode layer, the hole injection layer, the hole transport layer, the light-emitting layer, the electron transport layer, the electron injection layer and other structures via evaporation with an evaporation rate of 10 nm/s.

During the first evaporation, the second evaporation, the third evaporation, the fourth evaporation, the fifth evaporation and the sixth evaporation, vacuum degrees of the cavities are respectively less than or equal to 3×10⁻⁶ Torr (for example, 3×10⁻⁶ Torr, 2×10⁻⁶ Torr, 1×10⁻⁶ Torr, 0.5×10⁻⁶ Torr, and 0.1×10⁻⁶ Torr), which facilitates preparation of the electron injection layer, the cathode layer, the light-emitting layer, the electron transport layer, the hole transport layer, the hole injection layer, and other layer structures with high performance, and prevents side reaction during evaporation. For example, the light-emitting layer is a fluorescent light-emitting layer.

The light-emitting diode is encapsulated after the encapsulation layer is formed. Specifically, a glass cover plate may be used to encapsulate the main encapsulation area; then, UV curing adhesive is coated around the glass cover plate; and the light-emitting diode is placed under a 265-nm UV lamp for irradiation for 20-25 minutes.

According to another aspect of the present disclosure, a display panel is provided. The display panel includes a substrate and a light-emitting diode disposed on the substrate. The light-emitting diode is the foregoing light-emitting diode. Therefore, the light extraction efficiency of the OLED device in the display panel is high, that is, the EQE of the OLED device is high, which can effectively improve display quality of the display panel. Those skilled in the art can understand that the display panel has all the characteristics and advantages of the foregoing light-emitting diode, and details are not repeated herein.

Those skilled in the art can understand that, in addition to the foregoing light-emitting diode, the display panel further includes structures or components included in a conventional display panel. For example, the display panel further includes a base, a thin film transistor, a planarization layer, a pixel defining layer, an encapsulation film configured to encapsulate the OLED device, and other necessary structure or components.

According to still another aspect of the present disclosure, a display apparatus is provided. The display apparatus includes the foregoing display panel and a power supply component. The power supply component is configured to supply power to the display panel. Therefore, the light extraction efficiency of the OLED device in the display apparatus is high, that is, the EQE of the OLED device is high, which can effectively improve the display quality of the display apparatus. Those skilled in the art can understand that the display apparatus has all the characteristics and advantages of the foregoing display panel, and details are not repeated herein.

In this embodiment of the present disclosure, there is no special requirement on the specific type of the display apparatus. The display apparatus provided in this embodiment of the present disclosure may be a liquid crystal display apparatus, an organic light-emitting diode display apparatus, a quantum dot display apparatus, or the like. Those skilled in the art can choose flexibly according to actual requirements. In some embodiments, the specific type of the display apparatus includes but is not limited to a mobile phone, a notebook, an iPad, a Kindle, a game console, or the like which has a display function.

Those skilled in the art can understand that, in addition to the foregoing display panel, the display apparatus further includes structures or components included in a conventional display apparatus. For example, the display apparatus is a mobile phone. In addition to the foregoing display panel, the mobile phone further includes a glass cover plate, a shell, a CPU, an audio module, a camera module, a touch module and other necessary structures or components.

According to still yet another aspect of the present disclosure, a light-emitting apparatus is provided. In this embodiment of the present disclosure, the light-emitting apparatus includes the foregoing light-emitting diode. Therefore, the light extraction efficiency of the LED device in the light-emitting apparatus is high, that is, the EQE of the LED device is high, which can effectively improve the luminance and luminous intensity of the light-emitting apparatus. Those skilled in the art can understand that the light-emitting apparatus has all the characteristics and advantages of the foregoing light-emitting diode, and details are not repeated herein. For example, the light-emitting apparatus may include one, two or more light-emitting diodes.

For example, the light-emitting apparatus may be a lighting apparatus, such as a flashlight.

The embodiments of the present disclosure provide the following four experiments to verify the effect of the light-emitting diode provided in the embodiments of the present disclosure.

Experimental device 1:

The light-emitting diode structurally includes:

an anode layer made of ITO, wherein the resistance per unit area of ITO is less than 30 Ω/□;

a hole injection layer with a thickness of 10 nm and a refractive index of 1.6;

a hole transport layer with a thickness of 100 nm and a refractive index of 2.2;

a blue-light-emitting layer with a thickness of 25 nm and a refractive index of 1.7;

an electron transport layer with a thickness of 35 nm and a refractive index of 2.2;

an electron injection layer with a thickness of 10 nm and a refractive index of 1.6;

an optical coupling layer with a thickness of 65 nm; and

an encapsulation layer which includes a 1000-nm silicon oxynitride layer, an 8-μm IJP layer and a 600-nm silicon oxide layer.

The light-emitting area of the light-emitting diode is 3 mm×3 mm.

Contrast Device 1:

The light-emitting diode structurally includes:

an anode layer made of ITO, wherein the resistance per unit area of ITO is less than 30 Ω/□;

a hole injection layer with a thickness of 10 nm and a refractive index of 1.8;

a hole transport layer with a thickness of 100 nm thick and a refractive index of 1.8;

a blue-light-emitting layer with a thickness of 25 nm and a refractive index of 1.7;

an electron transport layer with a thickness of 35 nm and a refractive index of 1.8;

an electron injection layer with a thickness of 10 nm and a refractive index of 1.8;

an optical coupling layer with a thickness of 65 nm; and

an encapsulation layer which includes a 1000-nm silicon oxynitride layer, an 8-μm IJP layer and a 600-nm silicon oxide layer.

The light-emitting area of the light-emitting diode is 3 mm×3 mm.

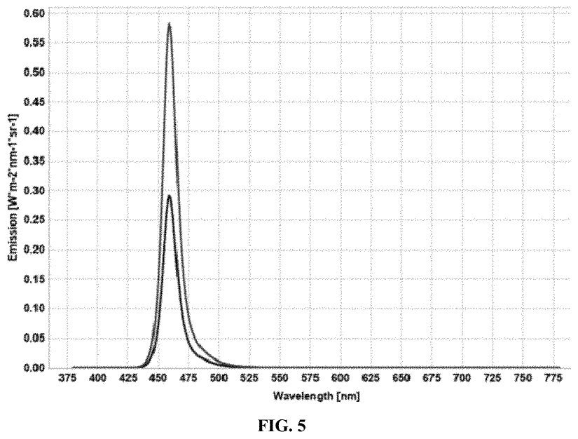

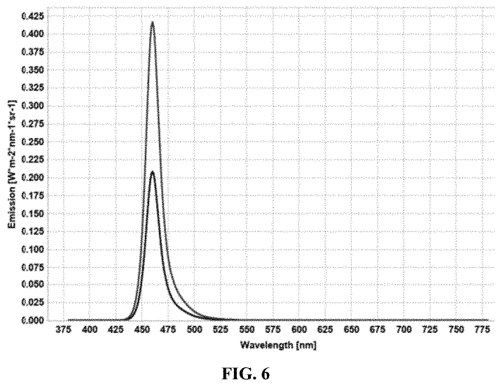

FIG. 5 is a luminescence spectrum diagram of an experimental device 1 according to an embodiment of the present disclosure. The x-coordinate represents the wavelength, and the y-coordinate represents emission. It can be known from FIG. 5 that the emission of experimental device 1 is about 0.58. FIG. 6 is a luminescence spectrum diagram of a contrast device 1 according to an embodiment of the present disclosure. As shown in FIG. 6, the emission of contrast device 1 is about 0.415. Compared with contrast device 1, the optical coupling output efficiency of the light-emitting diode in experimental device 1 is improved by about 40%, that is, the EQE is increased by about 40%. Both FIG. 5 and FIG. 6 have two curves. The curve with a smaller peak value represents only one mode, while the curve with a higher peak value represents the emission values.

Experimental Device 2:

The light-emitting diode structurally includes:

an anode layer made of ITO, wherein the resistance per unit area of ITO is less than 30 Ω/□;

a hole injection layer with a thickness of 10 nm and a refractive index of 1.6;

a hole transport layer with a thickness of 120 nm and a refractive index of 2.2;

a green-light-emitting layer with a thickness of 30 nm and a refractive index of 1.7;

an electron transport layer with a thickness of 35 nm and a refractive index of 2.2;

an electron injection layer with a thickness of 10 nm and a refractive index of 1.6;

an optical coupling layer with a thickness of 65 nm; and

an encapsulation layer which includes a 1000-nm silicon oxynitride layer, an 8-μm IJP layer and a 600-nm silicon oxide layer.

The light-emitting area of the light-emitting diode is 3 mm×3 mm.

Contrast Device 2:

The light-emitting diode structurally includes:

an anode layer made of ITO, wherein the resistance per unit area of ITO is less than 30 Ω/□;

a hole injection layer with a thickness of 10 nm and a refractive index of 1.8;

a hole transport layer with a thickness of 120 nm and a refractive index of 1.8;

a green-light-emitting layer with a thickness of 30 nm and a refractive index of 1.7;

an electron transport layer with a thickness of 35 nm and a refractive index of 1.8;

an electron injection layer with a thickness of 10 nm and a refractive index of 1.8;

an optical coupling layer with a thickness of 65 nm thick; and

an encapsulation layer which includes a 1000-nm silicon oxynitride layer, an 8-μm IJP layer and a 600-nm silicon oxide layer.

The light-emitting area of the light-emitting diode is 3 mm×3 mm.

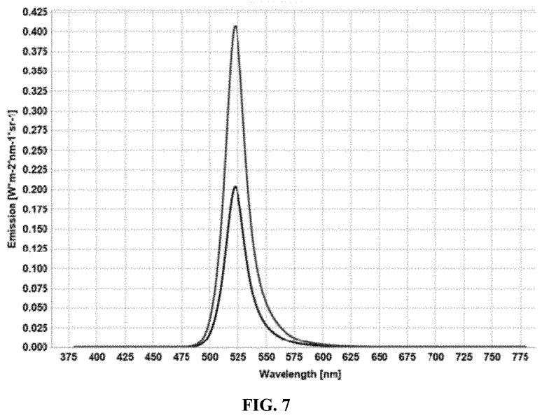

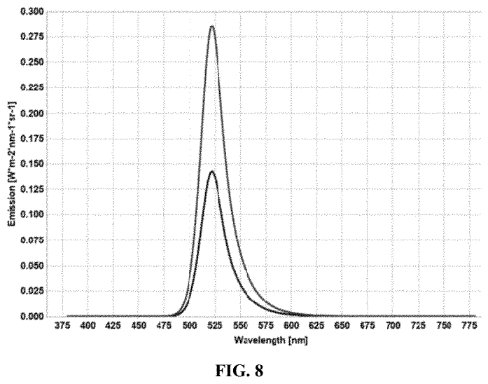

FIG. 7 is a luminescence spectrum diagram of experimental device 2 according to an embodiment of the present disclosure. As shown in FIG. 7, the emission of experimental device 2 is about 0.41. FIG. 8 is a luminescence spectrum diagram of contrast device 2 according to an embodiment of the present disclosure. As shown in FIG. 8, the emission of contrast device 2 is about 0.287. Compared with contrast device 2, the optical coupling output efficiency of the light-emitting diode in experimental device 2 is improved by about 42%, that is, the EQE is increased by about 42%. Both FIG. 7 and FIG. 8 have two curves. The curve with a smaller peak value represents only one mode, while the curve with a higher peak value represents emission values.

Experimental Device 3:

The light-emitting diode structurally includes:

an anode layer made of ITO, wherein the resistance per unit area of ITO is less than 30 Ω/□;

a hole injection layer with a thickness of 10 nm and a refractive index of 1.6;

a hole transport layer with a thickness of 150 nm and a refractive index of 2.2;

a red-light-emitting layer with a thickness of 15 nm and a refractive index of 1.7;

an electron transport layer with a thickness of 35 nm and a refractive index of 2.2;

an electron injection layer with a thickness of 10 nm and a refractive index of 1.6;

an optical coupling layer with a thickness of 65 nm; and

an encapsulation layer which includes a 1000-nm silicon oxynitride layer, an 8-μm IJP layer and a 600-nm silicon oxide layer.

The light-emitting area of the light-emitting diode is 3 mm×3 mm.

Contrast Device 3:

The light-emitting diode structurally includes:

an anode layer made of ITO, wherein the resistance per unit area of ITO is less than 30 Ω/□;

a hole injection layer with a thickness of 10 nm and a refractive index of 1.8;

a hole transport layer with a thickness of 150 nm and a refractive index of 1.8;

a red-light-emitting layer with a thickness of 15 nm and a refractive index of 1.7;

an electron transport layer with a thickness of 35 nm and a refractive index of 1.8;

an electron injection layer with a thickness of 10 nm and a refractive index of 1.8;

an optical coupling layer with a thickness of 65 nm; and

an encapsulation layer which includes a 1000-nm silicon oxynitride layer, an 8-μm IJP layer and a 600-nm silicon oxide layer.

The light-emitting area of the light-emitting diode is 3 mm×3 mm.

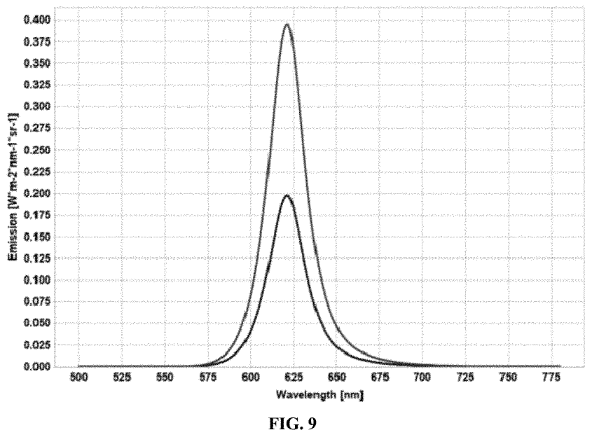

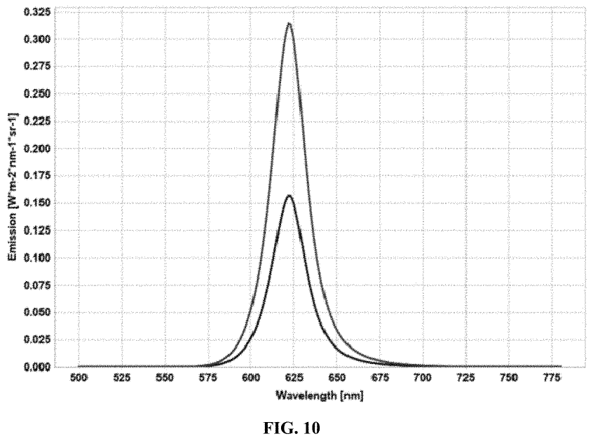

FIG. 9 is a luminescence spectrum diagram of experimental device 3 according to an embodiment of the present disclosure. As shown in FIG. 9, the emission of experimental device 3 is about 0.39. FIG. 10 is a luminescence spectrum diagram of contrast device 3 according to an embodiment of the present disclosure. As shown in FIG. 10, the emission of contrast device 3 is about 0.31. Compared with contrast device 3, the optical coupling output efficiency of the light-emitting diode in experimental device 3 is improved by about 25%, that is, the EQE is increased by about 25%. Both FIG. 9 and FIG. 10 have two curves. The curve with a smaller peak value represents only one mode, while the curve with a higher peak value represents the emission values.

Experimental Device 4:

The light-emitting diode structurally includes:

an anode layer made of ITO, wherein the resistance per unit area of ITO is less than 30 Ω/□;

a hole injection layer made of PEDOT:PSS, wherein the hole injection layer is 10 nm thick, and a refractive index of the hole injection layer is 1.52;

a hole transport layer made of MoO₃, wherein the hole transport layer is 40 nm thick, and a refractive index of the hole transport layer is 2.2;

a green-light-emitting layer made of CBP and Ir(PPY)3, wherein a mass percent of Ir(PPY)3 is 5%, and the green-light-emitting layer is 20 nm thick;

an electron transport layer made of Liq, wherein the electron transport layer is 25 nm thick, and a refractive index of the electron transport layer is 2.0;

an electron injection layer made of Bphen:Li, wherein the electron injection layer is 10 nm thick, and a refractive index of the electron injection layer is 1.7;

an optical coupling layer of a structure including a CPL layer and a LiF layer, wherein the CPL layer is 80 nm thick, and the LiF layer is 60 nm thick; and

an encapsulation layer including a 1000-nm silicon oxynitride layer, an 8-μm IJP layer and a 600-nm silicon oxide layer.

The light-emitting area of the light-emitting diode is 3 mm×3 mm.

Contrast device 4:

The light-emitting diode structurally includes:

an anode layer made of ITO, wherein the resistance per unit area of ITO is less than 30 Ω/□;

a hole injection layer made of MoO₃, wherein the hole injection layer is 10 nm thick, and a refractive index of the hole injection layer is 2.2;

a hole transport layer made of NPD, wherein the hole transport layer is 40 nm thick;

a green-light-emitting layer made of CBP and Ir(PPY)3, wherein a mass percent of Ir(PPY)3 is 5%, and the green-light-emitting layer is 20 nm thick;

an electron transport layer made of Liq, wherein the electron transport layer is 25 nm thick, and a refractive index of the electron transport layer is 2.0;

an optical coupling layer of a structure including a CPL layer and a LiF layer, wherein the CPL layer is 80 nm thick, and the LiF layer is 60 nm thick; and

an encapsulation layer including a 1000-nm silicon oxynitride layer, an 8-μm IJP layer and a 600-nm silicon oxide layer.

The light-emitting area of the light-emitting diode is 3 mm×3 mm.

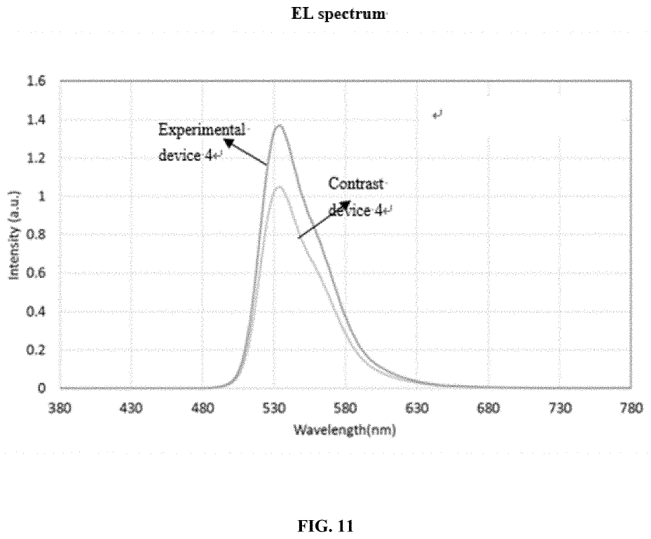

FIG. 11 is an electroluminescence spectrum diagram of experimental device 4 and contrast device 4 according to an embodiment of the present disclosure. It can be known from FIG. 11 that, compared with contrast device 4, the green-light intensity of the light-emitting diode in experimental device 4 is significantly increased under the same drive current (density of the current is 15 mA/cm²).

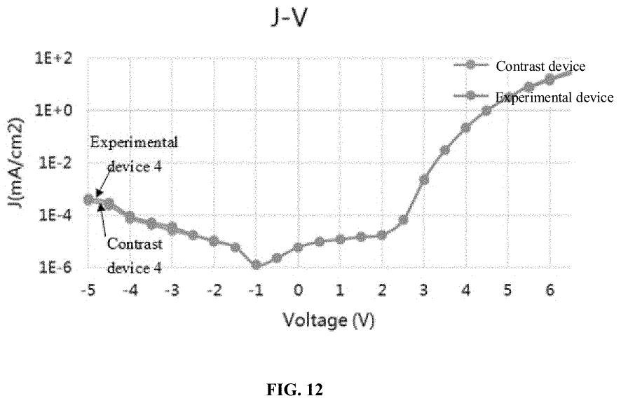

FIG. 12 is a J-V curve diagram of experimental device 4 and contrast device 4 according to an embodiment of the present disclosure. The x-coordinate represents the voltage (V), and the y-coordinate represents the current density (mA/cm²). It can be known from FIG. 12 that, the J-V curves of the light-emitting diodes in experimental device 4 and contrast device 4 basically overlap, which indicates that light extraction of the light-emitting diode in experimental device 4 is enhanced due to the micro-cavity gain and the electrode of the optical structure, and the light-emitting diode still has good electrical performance.

In the description, descriptions with reference to terms “an embodiment”, “some embodiments”, “an example”, “a specific example”, “some examples” or the like refer to that the specific feature, structure, material or characteristic described with reference to the embodiment or example is included in at least one of the embodiments or examples of the present disclosure. In this specification, illustrative descriptions of the above terms are not necessarily for the same embodiment or example. In addition, the specific features, structures, materials and characteristics described may be combined in an appropriate manner in any one or more embodiments or examples. Moreover, on the premise of no contradiction, those skilled in the art may integrate or combine different embodiments or examples, or features in the different embodiments or examples described in this specification.

Although the embodiments of the present disclosure have been illustrated and described above, it can be understood that the foregoing embodiments are examples and cannot be construed as restrictions on the present disclosure. Person of ordinary skill in the art may make changes, modifications, substitutions and variations to the foregoing embodiments, within the scope of the present disclosure.

What is claimed is:

1. A light-emitting diode, comprising an anode layer, a hole injection layer, a hole transport layer, a light-emitting layer, an electron transport layer, an electron injection layer and a cathode layer which are laminated sequentially, wherein the light-emitting diode meets at least one of the following conditions:
a refractive index of the hole transport layer is greater than a refractive index of the light-emitting layer; and
a refractive index of the electron transport layer is greater than the refractive index of the light-emitting layer.

2. The light-emitting diode according to claim 1, wherein the light-emitting diode meets the following conditions: the refractive index of the hole transport layer is not less than 2; the refractive index of the electron transport layer is not less than 2; a refractive index of the hole injection layer is not greater than 1.8; and a refractive index of the electron injection layer is not greater than 1.8.

3. The light-emitting diode according to claim 2, wherein the refractive index of the hole transport layer ranges from 2 to 2.5; the refractive index of the electron transport layer ranges from 2 to 2.5; the refractive index of the hole injection layer ranges from 1.5 to 1.8; and the refractive index of the electron injection layer ranges from 1.5 to 1.8.

4. The light-emitting diode according to claim 3, wherein the both refractive index of the hole transport layer and the refractive index the electron transport layer are 2.2, and both the refractive index of the hole injection layer and the refractive index of the electron injection layer are 1.6.

5. The light-emitting diode according to claim 1, wherein the hole injection layer is made of PEDOT:PSS, and the hole transport layer is made of MoO₃.

6. The light-emitting diode according to claim 1, wherein the electron transport layer is made of Liq, and the electron injection layer is made of Bphen:Li.

7. The light-emitting diode according to claim 1, wherein the refractive index of the light-emitting layer is not greater than 1.7.

8. The light-emitting diode according to claim 1, further comprising a reflective layer, wherein the anode layer is disposed between the reflective layer and the hole injection layer, and the light-emitting diode further meets at least one of the following conditions:
the refractive index of the hole transport layer is greater than the refractive index of the light-emitting layer, and a refractive index of the hole injection layer is less than the refractive index of the light-emitting layer; and
the refractive index of the electron transport layer is greater than the refractive index of the light-emitting layer, and a refractive index of the electron injection layer is less than the refractive index of the light-emitting layer.

9. The light-emitting diode according to claim 1, further comprising an optical coupling layer disposed on a surface of the cathode layer away from the anode layer, wherein the optical coupling layer comprises at least one sub-layer, a material of at least one of the at least one sub-layer is the same as a material of at least one of the hole transport layer and the electron transport layer.

10. The light-emitting diode according to claim 9, wherein the optical coupling layer comprises a capping layer (CPL) and a lithium fluoride layer, wherein the CPL is disposed between the cathode layer and the lithium fluoride layer, and the material of the hole transport layer is the same as a material of the CPL.

11. The light-emitting diode according to claim 1, wherein the light-emitting diode is an LED device or an OLED device.

12. A display panel, comprising a substrate and a plurality of light-emitting diodes disposed on the substrate; wherein each light-emitting diode comprises an anode layer, a hole injection layer, a hole transport layer, a light-emitting layer, an electron transport layer, an electron injection layer and a cathode layer which are laminated sequentially, and the light-emitting diode meets at least one of the following conditions:
a refractive index of the hole transport layer is greater than a refractive index of the light-emitting layer; and
a refractive index of the electron transport layer is greater than the refractive index of the light-emitting layer.

13. The display panel according to claim 12, wherein the light-emitting diode meets the following conditions:
the refractive index of the hole transport layer is not less than 2; the refractive index of the electron transport layer is not less than 2; a refractive index of the hole injection layer is not greater than 1.8; and a refractive index of the electron injection layer is not greater than 1.8.

14. The display panel according to claim 13, wherein the refractive index of the hole transport layer ranges from 2 to 2.5; the refractive index of the electron transport layer ranges from 2 to 2.5; the refractive index of the hole injection layer ranges from 1.5 to 1.8; and the refractive index of the electron injection layer ranges from 1.5 to 1.8.

15. The display panel according to claim 14, wherein both the refractive index of the hole transport layer and the refractive index of the electron transport layer are 2.2, and both the refractive index of the hole injection layer and the refractive index of the electron injection layer are 1.6.

16. A display apparatus, comprising a power supply component and a display panel, wherein the power supply component is configured to supply power to the display panel; and the display panel comprises a substrate and a plurality of light-emitting diodes disposed on the substrate; each light-emitting diode comprising an anode layer, a hole injection layer, a hole transport layer, a light-emitting layer, an electron transport layer, an electron injection layer and a cathode layer which are laminated sequentially, and the light-emitting diode meeting at least one of the following conditions:
a refractive index of the hole transport layer is greater than a refractive index of the light-emitting layer; and
a refractive index of the electron transport layer is greater than the refractive index of the light-emitting layer.

17. The display apparatus according to claim 16, wherein the light-emitting diode meets the following conditions:
the refractive index of the hole transport layer is not less than 2; the refractive index of the electron transport layer is not less than 2; a refractive index of the hole injection layer is not greater than 1.8; and a refractive index of the electron injection layer is not greater than 1.8.

18. The display apparatus according to claim 17, wherein the refractive index of the hole transport layer ranges from 2 to 2.5; the refractive index of the electron transport layer ranges from 2 to 2.5; the refractive index of the hole injection layer ranges from 1.5 to 1.8; and the refractive index of the electron injection layer ranges from 1.5 to 1.8.

19. The display apparatus according to claim 18, wherein both the refractive index of the hole transport layer and the refractive index of the electron transport layer are 2.2, and both the refractive index of the hole injection layer and the refractive index of the electron injection layer are 1.6.

20. A light-emitting apparatus, comprising a substrate and a light-emitting diode disposed on the substrate, wherein the light-emitting diode is the light-emitting diode as defined in claim 1.
